(19) United States
(12) Patent Application Publication
(10) Pub. No.: US 2016/0209446 A1
(43) Pub. Date: Jul. 21, 2016

(54) CURRENT TRANSFORMER SYSTEM WITH CHARACTERIZATION

(71) Applicant: SELEC CONTROLS PVT. LTD., Maharashtra (IN)

(72) Inventor: Samir KAJI, Navi Mumbai, Maharashtra (IN)

(73) Assignee: SELEC CONTROLS PVT. LTD., Navi Mumbai, Maharashtra (IN)

(21) Appl. No.: 14/912,399

(22) PCT Filed: Aug. 19, 2014
(86) PCT No.: PCT/IN2014/000529

§ 371 Date: Feb. 16, 2016

(30) Foreign Application Priority Data
Aug. 21, 2013 (IN) 2729/MUM/2013

(51) Int. Cl. G01R 15/18; H01F 38/38; G01R 35/02; H01F 38/32

(52) U.S. Cl. CPC G01R 15/183; H01F 38/32; H01F 38/38; G01R 35/02

(57) ABSTRACT

A current transformer system with characterization is disclosed. The current transformer system comprises at least one current transformer unit generating a secondary current output relative to a primary current input, and a characterizing circuit storing a set of characteristics measured under test conditions in a memory of the characterizing circuit which characteristics represent the relation between the primary current input and the secondary current output of the current transformer unit under various operating conditions, the characterizing circuit further communicating at least one of the characteristics via the communication interface to an onward device to allow dynamic compensation for any errors in the characteristics of the at least one current transformer unit at the device.

### TECHNICAL FIELD OF INVENTION

The present invention broadly relates to electric measurement devices. Particularly, the present invention relates to a current transformer system and method thereof for providing a means for an onward measuring device to compensate current transformer errors and enhancing measurement accuracy.

### BACKGROUND OF THE INVENTION

A current transformer is commonly used for measurement of electric current in AC circuits. A typical current transformer comprises a primary winding, a magnetic core, and a secondary winding. The magnetic core comprises a magnetic body having a defined relationship with one or more conductive windings. When an alternating current is passed through the primary winding, an alternating magnetic field is produced in the magnetic core, which induces an alternating current in the secondary winding. Depending on the application, the wire used in the secondary winding is connected to a meter that detects the current from the secondary winding and responsively provides an output indication which may be a measurement of current, voltage, and the like. In most electrical installations typically these measurements are converted into various derived outputs such as power, power factor, energy, and the like. The current transformers can be of different types such as an air-core (Rogowski coil) or a Hall-effect sensing.

In the state of art, the common errors encountered in the current transformer devices and the derived measurement thereof, include:
a. phase angle error—in which the currents flowing through the primary winding and the secondary winding are not in phase with each other such that to induce an error, thereby producing errors in the derived measurements such as power, energy, and the like;
b. magnetizing current error—the magnetizing core used in construction of current transformer needs magnetizing current, due to which the response curve of primary verses secondary current would deviates from being linear.
c. Non linearity due to core characteristics—due to non linear characteristics of B-H curve of core. B-H is the relationship between the flux density (B) in a piece of magnetized material and the magnetizing force (H) needed to produce the flux density. Each type of ferromagnetic material, material that contains iron and is magnetizable, has a different B-H curve. Due to B-H curve characteristics of core, the current transformer behavior of secondary verses primary current would be correspondingly non linear.
d. Load regulation error—in which the current transformer output deviates from linear response between primary and secondary currents based on the load conditions;
e. installation error—in which incorrect connection of the secondary winding wire or direction of the primary conduction passing through the core induces errors in the derived measurements; and
f. environmental error—in which environmental factors, particularly temperature, affect the winding or core performance, based on characteristics of the material used, which in turn induces an error in the current transformer output or the derived measurements.

A current transformer can be situated within a measuring device such as in a static electricity meter or can be remotely placed outside an electrical/electronic measuring, controlling, or tripping device such as a meter, a regulator or a protection relay device. When the current transformer is remotely placed the characteristics of the current transformer add to the errors in the connected electronic device and thereby produce inaccuracy in measurements. Often, when the current transformer is located within the electronic device the errors of the current transformer may be factored in and compensated for by the hardware/software in the electronic device and hence such errors can be mitigated.

However, for remote or externally connected current transformer systems, the sum of the individual accuracies of each, the current transformer and the device connected to it, will have to be within the total system accuracy requirement. Hence, for a 1.0% accurate system, the total of the accuracy of the current transformer and the device must be equal 1.0%; say, for example, 0.5% each. The combination accuracy therefore necessitates that the current transformer as well as the electronic device have better individual accuracies.

Several efforts have been made in the past to ameliorate the errors in current transformer measurements. U.S. Pat. No. 6,639,770 discloses a method for correcting asymmetries in a current transformer for a ground fault circuit breaker. The method comprises measuring the magnitude and orientation of the asymmetries, and altering the current transformer based on the measured magnitude and orientation of the asymmetries. In this method, the measuring of the magnitude and orientation of the asymmetries is obtained by locating an excitation conductor at the center of symmetry of a core prior to winding the multi-turn winding on the core, placing a pick-up coil next to the core, connecting an excitation source to the excitation conductor so that the core is excited by the excitation conductor; and monitoring the output of the pick-up coil. A drawback of the method is the numerous components and the steps thereof for measuring the asymmetries. Also, the suggested components such as the excitation conductor and the pick-up coil will have to be integrated within the current transformer system circuit, thus this technique cannot be used in cooperation with the known typical current transformer system.

U.S. Pat. No. 6,247,003 discloses a method and apparatus of correcting for saturation in a current transformer. The method and apparatus thereof uses a switching system which receives the current transformer output and determines within which of a plurality of ranges the current measurement falls, where depending on the range the output is provided to a protective device, or for correction to a first artificial neural system or a second artificial neural system. The said method applies a complex switching algorithm at the current transformer system, which increases cost of the device.

There is therefore felt a need for a current transformer system which overcomes the afore-noted drawbacks of the known current transformer systems by minimizing device errors and enhancing measurement accuracy at a reduced cost. Further, there is felt need for an improved method by which the errors of a current transformer may be treated for an improved result on the measuring device that connects to the current transformer.

### SUMMARY OF THE INVENTION

Some of the objects of the present invention, which at least one embodiment herein satisfies, are as follows:

It is an object of the present invention to provide a current transformer system and method thereof for providing a means for an onward measuring device to compensate current transformer errors and enhancing measurement accuracy by means of a characterizing circuit. It is also an object of the present invention to provide a current transformer system which is used to minimize load regulation, installation and environmental errors in the current transformer.

It is a further object of the present invention to provide a current transformer system which is simple, efficient, and cost-effective. Additionally, the modification of the present invention can be configured in a typical current transformer system.

Accordingly, the present invention discloses a current transformer system comprising:
at least one current transformer unit for receiving a primary current input to generate a secondary current output relative to said primary current input, said secondary current output being metered to an electronic device; and
a characterizing circuit attached to said at least one current transformer unit and electrically coupled to a communication interface;
wherein, the relation between said primary current input and said secondary current output of said current transformer unit under various operating conditions represent characteristics of said current transformer unit, a set of said characteristics measured under test conditions are stored in a memory of said characterizing circuit, said characterizing circuit being adapted to communicate at least one of said characteristics via said communication interface to said electronic device to allow dynamic compensation for any errors in said characteristics of said at least one current transformer unit at said electronic device.

Additionally, at least one connector terminal is provided for connecting said current transformer system to said electronic device.

Preferably, said characteristics stored in said characterizing circuit are selected from functional characteristics, environmental characteristics and current transformer specifications. More preferably, said functional characteristics are selected from linearity over operating range, phase angle errors and load conditions, said environmental characteristics are selected from temperature, pressure and humidity, and said current transformer specifications are selected from turns ratio, VA rating, VA accuracy class, serial number and the like.

Advantageously, a protection device is provided for preventing over voltage condition across said current transformer system.

Furthermore, a resistor is provided for converting said secondary current output to a voltage signal.

Typically, housing is provided for placing said at least one current transformer unit, said characterizing circuit and said communication interface.

Alternatively, said characterizing circuit and said communication interface are positioned remote from said at least one current transformer unit.

Additionally, said characterizing circuit comprises at least one sensor device for sensing environmental parameters including temperature, humidity and pressure.

In accordance with the present invention, said characterizing circuit can be applied to single-phase or multi-phase electrical network current transformer units.

The present invention further discloses a method for configuring a current transformer system, said method comprising the following steps:
receiving a primary current input across at least one current transformer unit to generate a secondary current output;
metering said secondary current output to an electronic device;
storing a set of characteristics measured under test conditions in a memory of a characterizing circuit, which characteristics represent the relation between said primary current input and said secondary current output of said current transformer unit under various operating conditions; and
communicating at least one of said characteristics from said characterizing circuit via said communication interface to said electronic device to allow dynamic compensation for any errors in said characteristics of said at least one current transformer unit at said electronic device to thereby provide optimum measurement accuracy in said electronic device.

The present invention and its advantages over the prior art will become more apparent upon reading the following detailed description and the appended claims with reference to the accompanying drawings.

### BRIEF DESCRIPTION OF THE ACCOMPANYING DRAWINGS

The present invention will be described here below with reference to the following drawings, in which,

FIG. 1 illustrates a block diagram showing the current transformer system in accordance with the present invention; and

FIG. 2 illustrates a circuit diagram showing a series of current transformer units in communication with the characterizing circuit, in accordance with the present invention.

### DETAILED DESCRIPTION OF THE INVENTION

The embodiments herein and the various features and advantages thereof are explained with reference to the non-limiting examples in the following description. The examples used herein are intended merely to facilitate an understanding of the ways in which the embodiments herein may be practiced and to further enable those of skill in the art to practice the embodiments herein. Accordingly, the examples should not be construed as limiting the scope of the embodiments herein.

The description herein after, of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

The present invention envisages a current transformer system including at least one current transformer unit and a characterizing circuit. The system can be used for compensating errors of the current transformer unit by means of the characterizing circuit operatively connected to the current transformer unit. The characterizing circuit contains data of the current transformer characteristics. The data stored in the characterizing circuit can be sent to an onward device that is connected to the current transformer system. The onward device may use the data to compensate for errors in the current transformer output readings in accordance with the characteristics recorded in the data under various operating conditions of use of the current transformer unit. One or more possible characteristics of the current transformer unit are stored into memory of the characterizing circuit; the characteristics may include linearity, load regulation, installation and environmental conditions, to provide adequate characteristics to an onward device to allow necessary correction in the measured output values to improve the accuracy of the final measurement by the onward device of the current transformer unit whose characteristics are stored in the characterizing circuit. The final parameters to be measured by the onward device could be the current passing through the current transformer unit or parameters derived with current being one of its components, for example, power, energy, power factor and others. The circuit of the present invention can be used along with a typical current transformer device having a core, primary windings, and secondary windings.

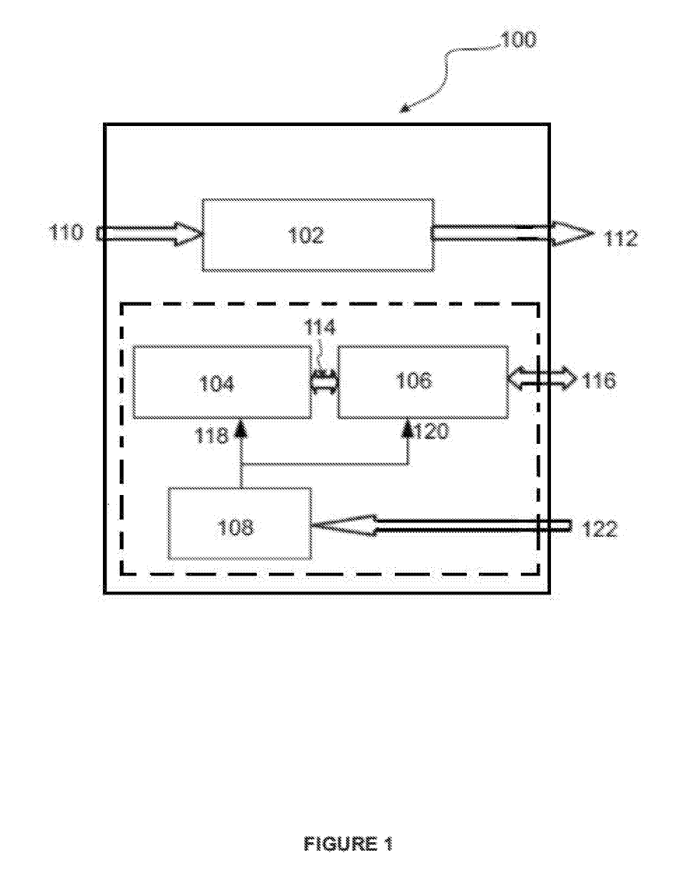

FIG. 1 of the accompanying drawings illustrates a block diagram of the current transformer system; the system is generally referenced by the numeral 100. The current transformer system 100 includes at least one current transformer unit 102 and the characterizing circuit 104. The characterizing circuit 104 is preferably a microcontroller and associated circuit having a storage means. The current transformer unit 102 is coupled to a primary current input 110. The current transformer unit 102 on receiving the primary current input 110 generates a secondary current output 112 relative to the primary current input 110. The secondary current output 112 is metered to an onward electrical/electronic device (not shown in Fig.).

The characterizing circuit 104 is attached to the at least one current transformer unit 102 and electrically coupled to a communication interface 106. The relation between the primary current input 110 and the secondary current output 112 of the current transformer unit 102 under various operating conditions represents characteristics of the current transformer unit 102. A set of the characteristics measured under test conditions are stored in the memory of the storage means of the characterizing circuit 104. The characterizing circuit 104 is adapted to communicate at least one of the characteristics via the communication interface 106 to the electronic device to allow dynamic compensation for any errors in the characteristics of the at least one current transformer unit 102 at the electronic device, thereby providing optimum measurement accuracy in the electronic device.

The characterizing circuit 104 is connected to the communication interface 106, as shown by the arrow 114. The characterizing circuit 104 stores data of at least one of the current transformer characteristics such as-
a. Functional Characteristics like linearity over operating range, phase angle errors and load conditions;
b. Characteristics against ambient conditions like temperature, pressure, humidity, etc.,
c. Specification and identification data like turns ratio, VA rating, VA accuracy class, serial number, etc.

The data within the characterizing circuit 104 pertains only to the current transformer unit whose characteristics are stored therein. The characterizing circuit 104 can be applied to single-phase or multi-phase electrical network current transformer units 102.

The electrical/electronic device may selectively request data relevant to the characteristics of the at least one current transformer unit 102 from the characterizing circuit 104. The characterizing circuit 104 through the communication interface 106 provides this data to the onward electrical/electronic device, as shown by arrow 116, which is adapted to make dynamic compensation for any errors in the secondary current output 112 at the electrical/electronic device. The secondary current output 112 may be attenuated, amplified or conditioned by the onward electrical/electronic device.

The data collected by the characterizing circuit 104 under test conditions of operation of the current transformer unit 102 records its characteristics such as:

a. Functional Characteristics like linearity over operating range, phase angle errors and load conditions;

b. Characteristics against ambient conditions like temperature, pressure, humidity, etc.,

c. Specification and identification data like turns ratio, VA rating, VA accuracy class, serial number, etc.

A resistor may be provided for converting current output to a voltage signal. Also, a mathematical function such as an integral or derivative of the current output may be derived. A protection device may be provided to prevent overvoltage condition across the current transformer unit 102. The current transformer output can be protected by overvoltage conditions by use of diodes, diode chain, Zener diodes, metal oxide varistors or any other clamping mechanism, that limits the output voltage across the current transformer unit 102.

The communication interface 106 is typically a transceiver. The characterizing circuit 104 has storage means that allow storage of the data that may be required for calculation of the compensation by the electrical/electronic device. The storage means is preferably a non-volatile memory. This data is collected during a selective operation span of the current transformer unit 102, may be determined and pre-fed during testing of the current transformer characteristics, and/or may be downloaded in the characterizing circuit 104. The characterizing circuit 104 may further comprise one or more sensor devices for sensing at least one environmental parameter from temperature, humidity, pressure, and the like. A real-time sensing of the environmental conditions can help in near accurate compensation of the secondary current output 112 of the current transformer unit 102 at the electrical/electronic device.

The current transformer system 100 is configured on a printed circuit board. At least one connector terminal is provided for connecting the current transformer system 100 to the electronic device. The characterizing circuit 104 and the communication interface 106 may be powered by a battery. Alternatively, the characterizing circuit 104 and the communication interface 106 may receive the power supply 108 at points 118 & 120, respectively, from the electronic device, as shown by the arrow 122. Also, the characterizing circuit 104 and the communication interface 106 may be adapted to receive the power supply from the current transformer 102. The current transformer 102, the characterizing circuit 104 and the communication interface 106 may be housed together. Alternatively, the characterizing circuit 104 and the communication interface 106 may be remotely located, plugged on to or placed outside the current transformer housing.

In accordance with the present invention, the Communication Link and the bus interface may be on any physical communication layer such as i2c, SPI, UART, wireless, and the like, or any other interface. The present invention may include a read/write command mechanism that is initiated by the apparatus host to either read the stored current transformer characteristic parameters or to write new characteristic values into the characterizing circuit 104.

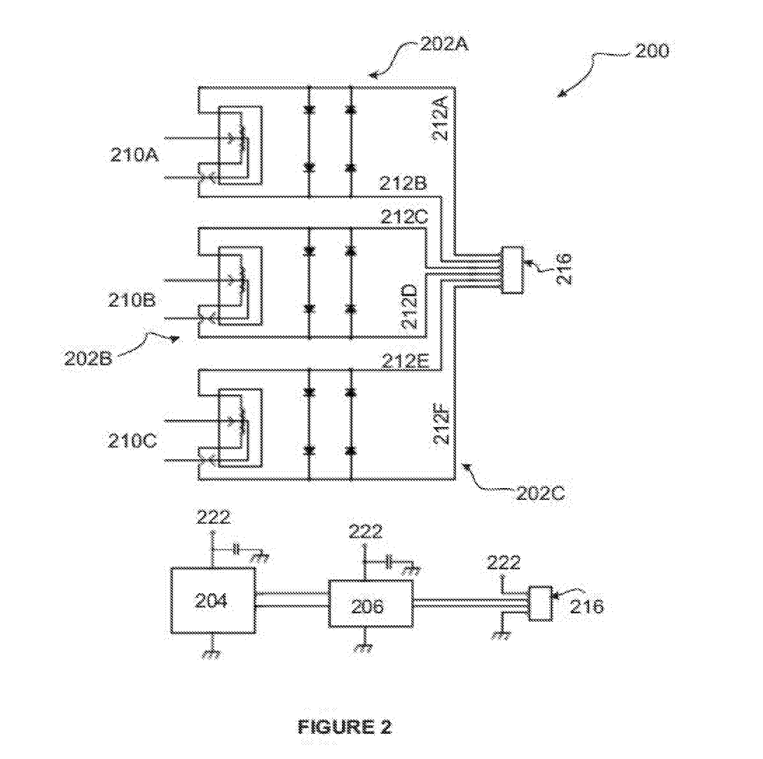

FIG. 2 of the accompanying drawings illustrates a series of current transformer units in communication with the characterizing circuit; the arrangement being generally referenced by the numeral 200 in the FIG. 2. A plurality of current transformer units 202A, 202B & 202C are connected in a three-phase system adapted to receive primary current inputs 210A, 210B & 210C and generate secondary current outputs 212A, 212B, 212C, 212D, 212E & 212F at the connector terminal 216. The characterizing circuit 204 is remotely connected to the current transformer units 202A, 202B & 202C through the connector terminal 216. The characterizing circuit 204 is operatively connected to the communication interface 206. The communication interface 206 is connected to the connector terminal 216. The power supply is shown by numeral 222. The secondary current outputs 212A, 212B, 212C, 212D, 212E & 212F are received at an onward electrical/electronic device (not shown in figure) through the connector terminal 216.

The electrical/electronic device may selectively request data relevant to the characteristics of the at least one current transformer units 202A, 202B & 202C from the characterizing circuit 204. The characterizing circuit 204 is adapted to provide the data to the electrical/electronic device through the communication interface 206 via the connector terminal 216. The secondary current outputs 212A, 212B, 212C, 212D, 212E & 212F may be compensated or conditioned at the electrical/electronic device, by a process as discussed above.

The apparatus and method of the present invention enhances the measurement accuracy of the multiple current transformer system, as shown in the FIG. 2. The phase angle errors and the magnetizing current error are completely nullified. With the apparatus described above, the current transformer accuracy is not a factor in the total accuracy of the electronic device, and the current transformer used could be less stringent and need only match the overall accuracy requirements. Thus, the present invention provides a current transformer system which gives higher measurement accuracy at a reduced cost.

Any discussion of documents, acts, materials, devices, articles or the like that has been included in this specification is solely for the purpose of providing a context for the invention. It is not to be taken as an admission that any or all of these matters form part of the prior art base or were common general knowledge in the field relevant to the invention as it existed anywhere before the priority date of this application.

Embodiment of the present invention is applicable over a wide number of uses and other embodiments may be developed beyond the embodiment discussed heretofore. Only the most preferred embodiments and their uses have been described herein for purpose of example, illustrating the advantages over the prior art obtained through the present invention; the invention is not limited to these specific embodiments or their specified uses. Thus, the forms of the invention described herein are to be taken as illustrative only and other embodiments may be selected without departing from the scope of the present invention. It should also be understood that additional changes and modifications, within the scope of the invention, will be apparent to one skilled in the art and that various modifications to the construction described herein may fall within the scope of the invention.

1. A current transformer system comprising:
at least one current transformer unit for receiving a primary current input to generate a secondary current output relative to said primary current input, said secondary current output being metered to an electronic device; and
a characterizing circuit attached to said at least one current transformer unit and electrically coupled to a communication interface;
wherein, the relation between said primary current input and said secondary current output of said current transformer unit under various operating conditions represent characteristics of said current transformer unit, a set of said characteristics measured under test conditions are stored in a memory of said characterizing circuit, said characterizing circuit being adapted to communicate at least one of said characteristics via said communication interface to said electronic device to allow dynamic compensation for any errors in said characteristics of said at least one current transformer unit at said electronic device.

2. The current transformer system as claimed in claim 1, wherein at least one connector terminal is provided for connecting said current transformer system to said electronic device.

3. The current transformer system as claimed in claim 1, wherein said characteristics stored in said characterizing circuit are selected from functional characteristics, environmental characteristics and current transformer specifications.

4. The current transformer system as claimed in claim 3, wherein said functional characteristics are selected from linearity over operating range, phase angle errors and load conditions.

5. The current transformer system as claimed in claim 3, wherein said environmental characteristics are selected from temperature, pressure and humidity.

6. The current transformer system as claimed in claim 3, wherein said current transformer specifications are selected from turns ratio, VA rating, VA accuracy class, serial number and the like.

7. The current transformer system as claimed in claim 1, wherein a protection device is provided for preventing overvoltage condition across said current transformer system.

8. The current transformer system as claimed in claim 1, wherein a resistor is provided for converting said secondary current output to a voltage signal.

9. The current transformer system as claimed in claim 1, wherein housing is provided for placing said at least one current transformer unit, said characterizing circuit and said communication interface.

10. The current transformer system as claimed in claim 1, wherein said characterizing circuit and said communication interface are positioned remote from said at least one current transformer unit.

11. The current transformer system as claimed in claim 1, wherein said characterizing circuit comprises at least one sensor device for sensing environmental parameters including temperature, humidity and pressure.

12. The current transformer system as claimed in claim 1, wherein said characterizing circuit can be applied to single-phase or multi-phase electrical network current transformer units.

13. A method for configuring a current transformer system, said method comprising the following steps:
receiving a primary current input across at least one current transformer unit to generate a secondary current output;
metering said secondary current output to an electronic device;
storing a set of characteristics measured under test conditions in a memory of a characterizing circuit, which characteristics represent the relation between said primary current input and said secondary current output of said current transformer unit under various operating conditions; and
communicating at least one of said characteristics from said characterizing circuit via said communication interface to said electronic device to allow dynamic compensation for any errors in said characteristics of said at least one current transformer unit at said electronic device to thereby provide optimum measurement accuracy in said electronic device.
